(19) United States
(12) Patent Application Publication
(10) Pub. No.: US 2025/0376757 A1
(43) Pub. Date: Dec. 11, 2025

(54) WATER SURFACE TENSION ENABLED HIGH QUALITY GRAPHENE TRANSFER

(71) Applicant: Georgia State University Research Foundation, Inc., Atlanta, GA (US)

(72) Inventors: Aisha Okmi, Lenoir City, TN (US); Sidong Lei, Atlanta, GA (US); Ningxin Li, Atlanta, GA (US)

(21) Appl. No.: 18/866,292

(22) PCT Filed: May 17, 2023
(86) PCT No.: PCT/US2023/022496

§ 371 Date: Nov. 15, 2024

Related U.S. Application Data
(60) Provisional application No. 63/342,878, filed on May 17, 2022.

(51) Int. Cl. C23C 16/01; C01B 32/186; C01B 32/196; C23C 16/26

(52) U.S. Cl. CPC C23C 16/01; C01B 32/186; C01B 32/196; C23C 16/26; C01B 2204/02; C01P 2002/82; C01P 2004/02; C01P 2004/03; C01P 2004/04

(57) ABSTRACT

The present disclosure describes various water surface tension enabled high quality graphene transfer systems, apparatuses, and related methods. One such method comprises growing a graphene layer on a metal catalyst substrate to form a graphene/metal sheet; positioning the graphene/metal sheet in a transfer reactor container, wherein the graphene/metal sheet is confined within an opening of a retainer frame that is also positioned in the transfer reactor container; introducing an etching solution to the transfer reactor container that removes the metal from the graphene/metal sheet to form a graphene sheet; replacing the etching solution with a rinsing liquid after removing the metal while the graphene sheet is confined in the opening of the retainer frame, wherein a graphene-water membrane is formed within the opening of the retainer frame as the graphene sheet floats on a surface of the rinsing liquid; and directly transferring the graphene-water membrane to a target substrate.

### CROSS-REFERENCE TO RELATED APPLICATION

This application claims priority to co-pending U.S. provisional application entitled, “Water Surface Tension Enabled High Quality Graphene Transfer,” having Ser. No. 63/342,878, filed May 17, 2022, which is entirely incorporated herein by reference.

### STATEMENT REGARDING FEDERALLY SPONSORED RESEARCH OR DEVELOPMENT

This invention was made with government support under Award No. 2105126 awarded by the National Science Foundation. The government has certain rights in the invention.

### TECHNICAL FIELD

The present disclosure is generally related to graphene transfer processes.

### BACKGROUND

The development of novel graphene-based electronics, quantum devices, micro-electromechanical systems (MEMS), and flexible biosensors explicitly depends on high-quality and large-scale graphene processing, particularly graphene transfer. Since large areas of free-standing graphene have not been achieved, auxiliary transfer membranes are typically required to sustain the graphene structure during the transfer. Striking examples of the membranes include polymethyl methacrylate (PMMA), paraffin, and other solvable organic (macro) molecules with good film-forming capability. Despite the fact that these free-standing membranes provide outstanding operational flexibility for the transfer process, they inevitably lead to concerns regarding mechanical deformation, contamination, and trapped interfacial residues that impact the performance of graphene-based devices for the previously mentioned applications. Polymer-free transfer in a full-liquid environment avoids using organic films and thus eliminates the contamination. However, deformation and interfacial residue still exist because this process typically requires immersing the target substrates or device structures entirely under the liquid, limiting the feasibility of such a method, particularly for target substrates that are incompatible with water.

### SUMMARY

Embodiments of the present disclosure provide water surface tension enabled graphene transfer systems, apparatuses, related methods, and novel materials. One such method comprises growing a graphene layer on a metal catalyst substrate to form a graphene/metal sheet; positioning the graphene/metal sheet in a transfer reactor container, wherein the graphene/metal sheet is confined within an opening of a retainer frame that is also positioned in the transfer reactor container; introducing an etching solution to the transfer reactor container that removes the metal from the graphene/metal sheet to form a graphene sheet; replacing the etching solution with a rinsing liquid after removing the metal while the graphene sheet is confined in the opening of the retainer frame, wherein a graphene-water membrane is formed within the opening of the retainer frame as the graphene sheet floats on a surface of the rinsing liquid; and directly transferring the graphene-water membrane to the target substrate.

In one or more aspects for such a method, the graphene is grown on two sides of the metal catalyst substrate, the metal catalyst substrate is copper, the retainer frame is formed from a polyethylene terephthalate (PET) film, the retainer frame comprises a hydrophilic frame, the graphene-water membrane is directly transferred by lifting the retainer frame from the transfer reactor container and placing the retainer frame on the target substrate, the retainer frame with the graphene-water membrane is lifted and flipped over onto the target substrate, a peeling angle at which the retainer frame is lifted is approximately 57.5 degrees from a surface of the rinsing liquid, a peeling angle at which the retainer frame is lifted is at least 54.1 degrees from a surface of the rinsing liquid, the graphene-water membrane is directly transferred by positioning the target substrate under the opening of the retainer frame within the transfer reactor container and drawing the rinsing liquid out of the transfer reactor container, no polymers are coated on the graphene during removal of the metal via etching, no organic solvents are introduced to remove polymer remnants after transferring graphene to target substrate, the rinsing liquid is deionized water, a surface tension of the rinsing liquid does not match a surface tension of the etching solution used to remove the metal, the rinsing liquid is a deionized water and Isopropyl Alcohol (IPA) mixture, wherein an IPA concentration of the rinsing liquid is less than 3 percent, the target substrate comprises a semi-liquid substrate, the target substrate comprises ionic hydrogel, the transfer reactor container is formed from polytetrafluoroethylene, the transfer reactor container comprises a hydrophobic material, and/or the target substrate is not immersed in the rinsing liquid during the transfer of the graphene onto the target substrate.

In one or more aspects, such method may further perform removing graphene from one side of the metal catalyst substrate via plasma etching and preserving the graphene layer on the other side of the metal catalyst substrate, wherein the graphene is grown on two sides of the metal catalyst substrate.

The present disclosure can also be viewed as a novel graphene coated substrate comprising a target substrate; and a graphene layer atop of the target substrate, wherein a surface roughness of the graphene layer on the substrate is less than 2.9 nm. In one or more aspects, the graphene coated substrate may also have a surface roughness of the graphene layer on the substrate be approximately 0.7 nm, the target substrate comprising a hydrophobic material, and/or wherein the target substrate comprising a semiconductor, metal, or organic substrate.

The present disclosure can also be viewed as a novel graphene coated substrate comprising a target substrate; and a graphene-water membrane atop of the target substrate. In one or more aspects, the target substrate may comprise a hydrophobic material, a semiconductor, metal, or organic substrate.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A demonstrates a plasma treatment fixture in accordance with embodiments of the present disclosure.

FIG. 1B is an image of a prototype of a reactor in accordance with embodiments of the present disclosure.

FIG. 1C shows an exemplary workflow of copper etching, graphene releasing, and rinsing processes in accordance with embodiments of the present disclosure.

FIG. 2A shows transfer reactor and retainer frame assemblies in accordance with embodiments of the present disclosure.

FIG. 2B shows transfer reactor and retainer frame assemblies holding a graphene/copper piece or sheet in accordance with embodiments of the present disclosure.

FIG. 2C shows transfer reactor and retainer frame assemblies holding graphene over a target substrate in accordance with embodiments of the present disclosure.

FIG. 3A shows a table comparing surface tension (ST) values and surface tension gap (STG) values that match Isopropyl Alcohol (IPA) ratios in accordance with embodiments of the present disclosure.

FIG. 3B shows a graph of final ST values versus IPA ratios in accordance with embodiments of the present disclosure.

FIG. 3C shows a graph of final STGs versus. IPA ratios in accordance with embodiments of the present disclosure.

FIGS. 4A-4B show prototype and model images of transfer reactor and retainer frame assemblies holding a graphene/copper piece in accordance with embodiments of the present disclosure.

FIGS. 4C-4D demonstrate transfer of graphene onto a SiO₂ substrate using the reactor and retainer frame assemblies in accordance with embodiments of the present disclosure.

FIG. 5 shows images of graphene on copper during copper etching and defective graphene with edge deformations after the copper is fully etched in accordance with an embodiment of the present disclosure.

FIGS. 6A-6D show images of an embodiment of transferring graphene to a SiO₂ substrate in accordance with the present disclosure.

FIG. 7A shows a Raman shift of monolayer graphene transferred on SiO₂ after applying a maximum surface tension gap (40 dyne/cm), where the inset image shows an atomic force microscopy (AFM) image of the graphene in accordance with an embodiment of the present disclosure.

FIG. 7B shows a transmission electron microscopy (TEM) image of single-layer graphene transferred with pure deionized water (DI-water) in accordance with an embodiment of the present disclosure.

FIG. 7C shows a scanning TEM (STEM) image of graphene transferred with GWM with the main image showing a clean graphene surface, and the inset image clearly distinguishing carbon atoms.

FIG. 7D shows an scanning electron microscopy (SEM) image of free-suspended graphene directly produced by the GWM, with the magnified image (inset) showing no contamination.

FIG. 7E shows a Raman spectrum of free-suspended graphene in accordance with various embodiments of the present disclosure.

FIGS. 8A-8C show images of a whole device transfer during an embodiment of the present disclosure.

FIGS. 9A-9B are an I-V graph of field-effect transistor (FET) mobility based on high quality graphene transferred on a target SiO₂ substrate and an I-V graph of FET mobility of a defective graphene transferred on a target SiO₂ substrate, respectively, in accordance with embodiments of the present disclosure.

FIG. 10A shows an optical image of a graphene peeling process in accordance with an embodiment of the present disclosure.

FIG. 10B shows an image of a free-standing graphene-water membrane held by a retainer frame in accordance with an embodiment of the present disclosure.

FIG. 10C shows a relationship between peeling angle and contact angle as criteria of a successful graphene peeling process in accordance with an embodiment of the present disclosure.

FIG. 10D shows a contact angle measurement of water on a graphene surface in accordance with an embodiment of the present disclosure.

FIG. 10E shows a molecular dynamics simulation of a graphene peeling process in accordance with the present disclosure.

FIG. 10F shows a plot of the evolution of peeling force as a function of peeling time and IPA concentration in accordance with the present disclosure.

FIG. 10G is a model image of a graphene peeling process and the relationship between a smaller contact angle requiring a larger peeling angle and a resulting increased risk of peeling failure in accordance with the present disclosure.

FIG. 11A shows a Raman spectrum of an as-transferred graphene layer with an inset of an optical image of the as-transferred graphene in accordance with an embodiment of the present disclosure.

FIG. 11B shows an AFM image of graphene transferred on an Si/SiO₂ wafer with a graphene-water membrane in accordance with an embodiment of the present disclosure.

FIG. 11C shows a model image of a conventional graphene transfer method with a target substrate submerged into a liquid and wrinkles forming after liquid evaporation.

FIG. 11D shows an AFM image of graphene transferred onto an Si/SiO₂ wafer with the conventional polymer-free procedure of FIG. 11C.

FIG. 11E shows a model simulation image of no water or IPA molecules adhering to the graphene layer during the peeling process in accordance with embodiments of the present disclosure.

FIG. 11F illustrates a graphene transfer procedure that involves flipping the graphene-water membrane to further eliminate water trapping on interfaces in accordance with embodiments of the present disclosure.

FIG. 11G shows an AFM image of graphene after the flipping transfer of FIG. 11F, with improved flatness and transfer quality.

FIGS. 11H and 11I show FET measurement translation curves of graphene layers transferred with (H) an exemplary graphene-water membrane and (I) a conventional method, respectively, with the inset of FIG. 11I showing an example graphene FET device array used in the measurement.

FIG. 12A shows an exemplary graphene-water membrane transfer process whereby graphene is transferred onto a hydrophobic substrate with the assistance of a hydrophilic retainer frame in accordance with embodiments of the present disclosure.

FIG. 12B shows an optical image of graphene transferred onto silicon with a SiO₂ frame serving as a hydrophilic frame in accordance with the exemplary graphene-water membrane transfer process of FIG. 12A.

FIG. 12C shows an AFM image of as-transferred graphene on the silicon surface shown in FIG. 12B.

FIG. 12D shows an image of a graphene layer transferred on a hydrogel target substrate (1 g of agar and 0.2 g gelatin dissolved in 100 ml DI water) in accordance with an embodiment of the present disclosure.

### DETAILED DESCRIPTION

The present disclosure describes various embodiments of water surface tension enabled high quality graphene transfer systems, apparatuses, and methods that utilize liquid membranes instead of solid ones to drastically improve graphene material quality. In accordance with the present disclosure, a free-standing graphene-water membrane (GWM) structure can effectively eliminate the contamination caused by organic macromolecules. More interestingly, the GWM produces excellent graphene flatness, due to the high water surface tension, which has long been misinterpreted to jeopardize the graphene transfer process. The present disclosure offers an alternative pathway of graphene processing for novel electronics applications.

In various embodiments, an exemplary free-standing graphene-water membrane structure can be obtained in an opening of a polyethylene terephthalate frame. Experimental observation, theoretical modeling, and molecular dynamics simulations consistently suggest and confirm that the high surface tension of pure water and its large contact angle with graphene are essential factors for forming such a membrane structure. The membrane can be readily transferred to target substrates, which drastically improves electronic performances due to less interface contamination and, more importantly, due to the remarkable surface flatness induced by water surface tension within the membrane during the lamination process.

The successful formation of the GWM involves several precautionary measures to ensure graphene quality and integrity. The graphene employed in an embodiment of the present disclosure is synthesized on a metal catalyst (e.g., copper foils) in, but not limited to, a regular chemical vapor deposition (CVD) system based on a tube furnace. It has a leakage rate lower than 10⁻⁹ bar·cm³/s, which has been carefully confirmed with a helium leak detector prior to each growth cycle. Otherwise, a high density of defects can develop on the graphene layer, primarily when the leakage rate is higher than 10⁻⁷ bar·cm³/s. Following the growth, the graphene on one surface of the copper foil is preserved and the graphene layer deposited on the opposite surface/side is removed with plasma etching.

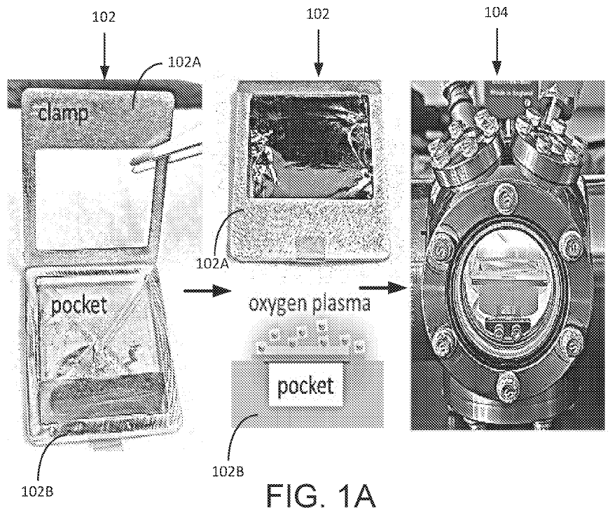

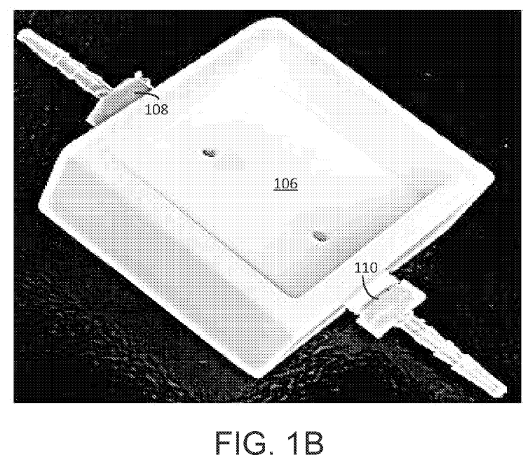

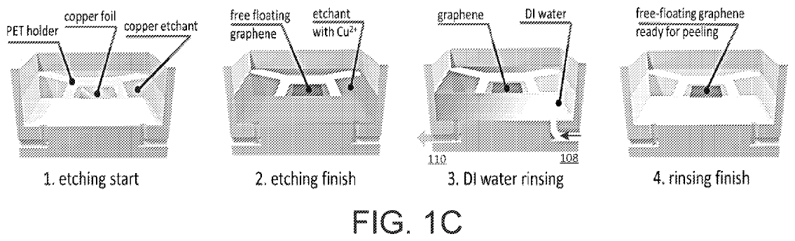

Conventionally, a thin film of polymer may be coated on the preserved surface and can lead to contaminations or residues. Thus, in accordance with various embodiments of the present disclosure, this process is improved by introducing a plasma treatment fixture, as demonstrated in FIG. 1A, that features a metal clamp fixture 102 having a top bronze clamp 102A and a bottom copper platform 102B with a pocket. The top bronze clamp 102A presses the copper foil flat onto the bottom platform 102B, allowing a Faraday cage to form between the foil and copper pocket, fully shielding the oxygen plasma from bombarding the preserved graphene layer. The pocket eliminates physical contact with the delicate preserved graphene layer and ensures its integrity during plasma etching. It can be noted that, for certain embodiments, argon was used instead of oxygen plasma for the etching because ozone generated in the oxygen plasma could potentially penetrate the pocket and oxidize the graphene layer. These efforts ensure the graphene quality and integrity to the maximum extent. In various embodiments, the graphene is synthesized on a metal catalyst layer (e.g., copper foil) in a chemical vapor deposition (CVD) system based on a tube furnace 104. The metal catalyst layer itself may comprise any suitable metal or metal-inclusive material, such as but not limited to copper. Thus, in various embodiments, an exemplary transfer method of the present disclosure is directed to Metal-CVD, in which copper, nickel, ruthenium, palladium, platinum, iridium, cobalt, gold, rhodium, etc., can be served as a catalyst.

With the preserved graphene layer facing up, the copper foil is relocated into a specially designed transfer reactor 106, as shown in FIG. 1B, filled with a 0.1mol/L ammonium persulfate ((NH₄)₂S₂O₈) water solution for copper etching for 3 hours, leaving a two-dimensional (2D) monolayer graphene on the etchant surface. Due to the high surface tension of water (72 mN/m), the thin copper film and the finally released graphene float freely on the surface and are confined by a polyethylene terephthalate (PET) frame with a 1×1 cm² opening in the center. Subsequently, the etchant is exchanged with deionized (DI) water and the graphene monolayer is rinsed several times to remove all ions, including Cu²⁺ generated during the etching step illustrated in FIG. 1C. To avoid liquid turbulence or fluctuation during the exchange and ensure the integrity of the graphene layer, source inlet 108 and drain outlet ports 110 are designed on the bottom of the reactor, through which the liquid is injected and drained at the same rate.

A widely accepted view is that large areas of free-standing CVD graphene can be easily destroyed by pure water because of the water's high surface tension. However, for the demonstrated GWM of the present disclosure, no deformations were observed to be generated through the entire process which suggests CVD graphene can withstand the high surface tension of DI water as long as the described precautions are followed that include: first: growing graphene with the minimum avoidable level of O₂ leakage, meaning that the growth chamber must be sealed in a way that does not allow oxygen leakage into the chamber; and second: the exchange of etchant for the rinsing solution (e.g. DI water) should happen gradually and slowly to guarantee no surface interruption would happen and jeopardize the graphene integrity. Otherwise, defects developed during growth and physical damage due to improper handling can impair the graphene layer, leading to cracks, wrinkles, shrinking, etc.

Conventional graphene transfer techniques can be classified into two categories: polymer-assisted transfer techniques [55-56] and polymer-free direct transfer techniques. In general, polymer-assisted transfer techniques remove the effect of surface tension by spin coating polymer on the graphene to provide enough surface support during catalyst etching (copper usually) and transferring which leads to two main disadvantages. First, the graphene transferred using this method is usually highly contaminated and requires annealing at high temperature to remove the chemical residues. However, annealing graphene interrupts the super electrical properties of graphene, which raises the demand to invent methods that do not require annealing to remove chemical residues. Second, this type of transfer requires using an organic solvent (such as acetone) after moving graphene to the target substrate to remove polymer remnants and finalize graphene transfer to the target substrate to be used in the aimed applications. This means that there is a wide range of substrates that cannot be used if this type of transfer is applied. Thus, polymer-assisted transfer techniques unavoidably contaminate graphene with polymer residue and interfere with the electronic properties. [57,58].

Therefore, polymer-free direct transfer techniques have emerged to address this problem by allowing graphene to float freely on the surface of transfer liquids, and then be picked up with the target substrate directly from the liquid. This type of transfer depends on reducing the effect of surface tension of water by adding other liquids to DI water to reduce the surface tension to achieve successful transfer. For example, isopropyl alcohol (IPA) can be used to reduce the surface tension of the etching and rinsing solution. Although the previous polymer-free transfer methods are conducive with a wider selection of target substrates, they also have disadvantages. First, they require surface tension matching. For example, if IPA is used to reduce water surface tension of the etchant, the surface tension of the rinsing solution should be matched with that of the etching solution. However, IPA usually slows the etching procedure and can prolong the etching procedure to take 7-12 hours instead of 3-4 hours, as an example. The main problem of prolonging catalyst copper etching is that Gr/Cu would be oxidized before the full etching of copper, which affects the final graphene quality. Second, most non-polymer graphene transfer techniques are complicated and sometimes this complication affects the graphene quality. For example, trapping graphene in between etchant and hexane produces the need to freeze this combination (hexane/graphene/etchant) for several hours before finalizing the transfer. Another example would be replacing polymer with wax (such as paraffin) or other materials that do not require organic solvents but produce contaminated and defective graphene. In addition, the whole transfer process typically needs to be performed at high temperatures. Accordingly, for methods that do not coat liquid polymer to transfer graphene, these methods mainly involve other materials such as hexane, paraffin, and solid plastic films such as polyvinyl alcohol polymer (PVA), that impede the final graphene quality.

Another conventional method involves mixing IPA with copper etchant solution to reduce the effect of surface tension to accomplish graphene transfer. However, this method requires a long and inefficient transfer because of micro-sized non-etched copper in the resultant graphene.

Finally, conventional graphene transfer techniques (whether polymer-assisted or polymer-free) are based on manipulation of the surface tension, which was errantly assumed to be the main reason for graphene transfer failure. This long-held belief has led to the creation of many overly-complicated transfer techniques that involve reducing surface tension, and while such techniques have been successful with some substrates, they fail with many others because surface tension was never the underlying reason for transfer failure. Instead, initial defects that can be formed during the chemical vapor growth are the main reason for an unsuccessful transfer. And, while surface tension does not affect the transfer, it provides an effective and non-complicated way to achieve a successful direct transfer of monolayer graphene, in accordance with embodiments of the present disclosure.

As briefly stated above, compared with the polymer-assisted methods, polymer-free transfer or direct transfer can yield a high-quality contamination-free graphene layer. In this process, a high ST has long been believed to be destructive on monolayer graphene transfer due to the possible tearing, folding, and wrinkling. Thus, many efforts have focused on reducing the ST value of transfer liquid. For example, water/isopropyl alcohol mixtures are usually applied to adjust ST values to ensure the success of the transfer. Nevertheless, there is, hitherto, no specific theoretical explanation or experimental demonstration to illustrate how the ST affects graphene transfer. Further, although the mechanical properties of graphene have been studied widely, none of the studies clearly indicates that a high ST can damage the monolayer free-floating graphene. Then, the question turns out to be whether the high ST truly damages monolayer graphene during the direct transfer or this is just an intuitive judgment.

To answer this question, the present disclosure explores the actual effects of the ST on graphene during the direct transfer process by tuning the ingredients of the transfer liquid and proving that high quality graphene can always withstand a high ST (ST of pure water). Further, by exchanging pure water with transfer liquids that have lower ST, it was found that the same graphene monolayer can sustain a broad variation in ST without showing any sign of damage. Specifically, the same graphene layer could survive in deionized water (DI-water, with ST of 72 dyne/cm) as well as 80:20 water/IPA mixture (32 dyne/cm). This large STG of 40 dyne/cm provides significant flexibility in selecting transfer liquid for specific applications. On the other hand, STG was applied to defective graphene and revealed that the damage that occurs to the graphene at high ST results from defects in the graphene structure. The present research indicates that surface tension is not the cause of graphene damage during the polymer-free transfer process. The feasibility of using pure water for graphene transfer significantly simplifies the transfer procedure and effectively addresses the contamination problem. Further, the large STG the high-quality graphene layers can withstand provides extreme flexibility for selecting transfer liquids aiming at various application purposes.

For certain embodiments, graphene was synthesized using the CVD method. Copper foil 25 μm thickness (CU 00035 copper foil, purity 99.99) from Goodfellow was used as a metal catalyst. The copper was electropolished in phosphoric acid 85% for two minutes. Later, DI-water and IPA were used sequentially to remove the phosphoric acid residues. Then, the copper was launched in a quartz tube, 22 mm ID, 25 mm OD. A thermal CVD system was used to achieve the growth. The graphene growth was done at 1010° C. The gases that were used as precursors are methane CH₄ with a flow rate of 35 sccm and a mixture of argon and hydrogen (Ar 90%: H₂ 10%) with a flow rate of 6 sccm. Later, O₂ plasma cleaner was used to etch graphene that was grown on the bottom side of the copper. Following this step, monolayer graphene was grown with full coverage. Additionally, another batch of defective graphene was grown for the purpose of comparing the transfer results. The defective graphene can be produced in two ways: allowing O₂ leakage during the growth or by inserting the intact graphene/copper into O₂ plasma for a few seconds.

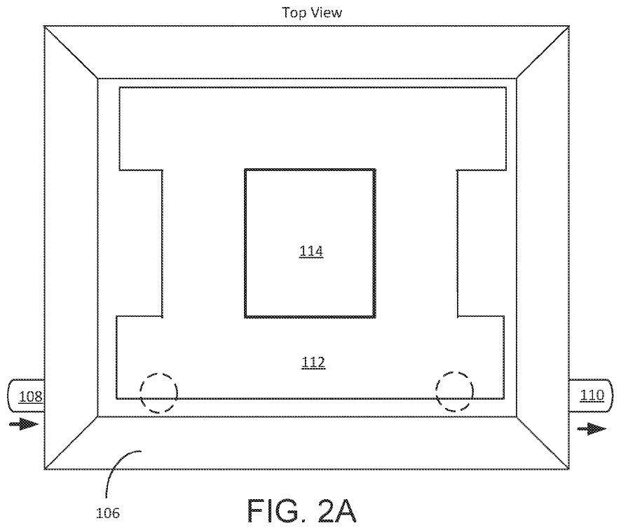

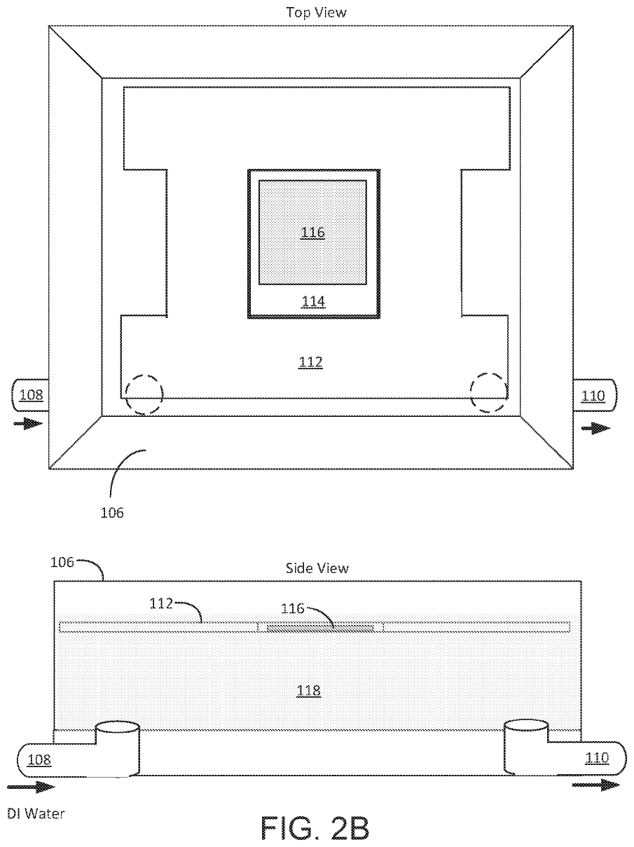

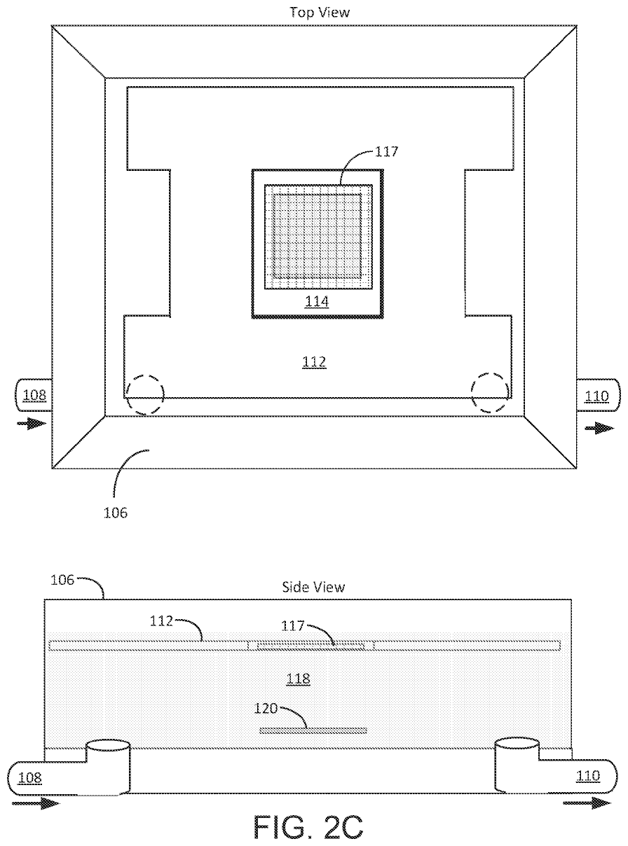

To perform the transfer job, a specific container (transfer reactor 106) was designed that can be used not only to achieve the transfer but also to facilitate the replacement of the liquids and enable graphene to float on liquids with different ST values. A top view of the design is shown in FIG. 2A and a prototype image is provided in FIG. 1B. It is noted that the transfer reactor 106 has two-side openings (source inlet 108 and drain outlet 110) to insert liquids into the transfer reactor and pull them out later. In various embodiments, the transfer reactor 106 is formed from a polytetrafluoroethylene (Teflon) material or another type of hydrophobic material. During the copper etching, rinsing, and transferring processes, a thin film frame formed from a PET sheet (Polyethylene Terephthalate) was used to make a protector or retainer frame/holder 112 as also shown in FIG. 2A. A purpose of the retainer frame 112 is to provide a center opening 114 that protects graphene from any possible disturbance while exchanging the liquids within the transfer reactor 106. In addition, the retainer frame 112 locates the graphene piece or sheet in the same spot (e.g., center opening 114) to ease the transfer to the target substrate later. For various embodiments, the reactor 106 and retainer frame 112 assemblies can be of different sizes (e.g., 2×2 inches, 4×4 inches, etc.) as needed to scale up the production of transferred graphene.

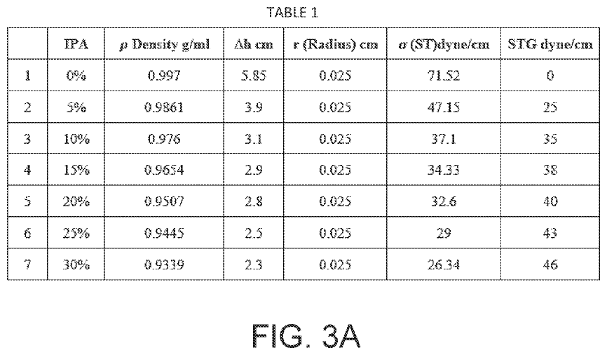

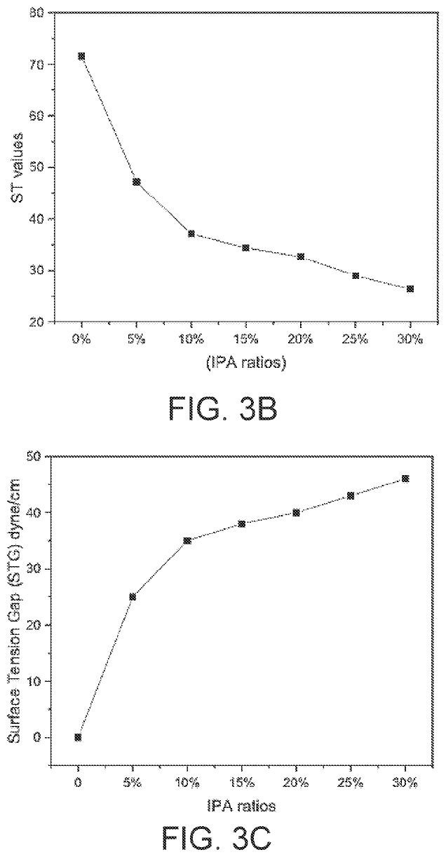

For copper etching, a solution of (0.1 M) ammonium persulfate (CH₄)₂S₂O₈was prepared. After rinsing with DI-water, O₂ plasma was used to enhance the substrate hydrophilicity to finalize the transfer successfully. The ST of water can be reduced by mixing water with liquids that have lower surface tension, such as IPA or methanol. The ST value of DI water is approximately 72 dyne/cm while the ST of IPA is approximately 21 dyne/cm. Adding IPA to DI-water at different ratios produces mixtures with ST values lower than 72 dyne/cm and higher than 21 dyne/cm. To calculate the final value of the resultant ST, the capillary action of each mixture was measured. Table 1 (as shown in FIG. 3A) and FIG. 3B show the resultant ST values corresponding to various percentages of water/IPA mixtures. The first mixture was 5% of IPA and 95% of DI-water with a final ST of 47 dyne/cm, which creates an STG of 25 dyne/cm, as shown in FIG. 3C. The IPA ratio was gradually increased to 10% to provide a final surface tension of approximately 37 dyne/cm. Next, a 20% IPA: 80% water mixture reduced the surface tension of water to 32 dyne/cm. Finally, approximately 26 dyne/cm was reached by increasing the IPA ratio to 30%. All STG values corresponding to IPA mixtures are shown in Table 1 (FIG. 3A) and FIG. 3C. In all cases, capillary tubes were used with an inner diameter (ID) of 0.25 mm to measure the capillary action of each mixture. Three syringes were filled with 30 ml of IPA mixture to be used on the right side of the reactor in sequence to insert the 5%, 10%, 20% IPA mixtures into a source inlet, while on the left side, there was an empty syringe to pull each mixture out of a drain outlet.

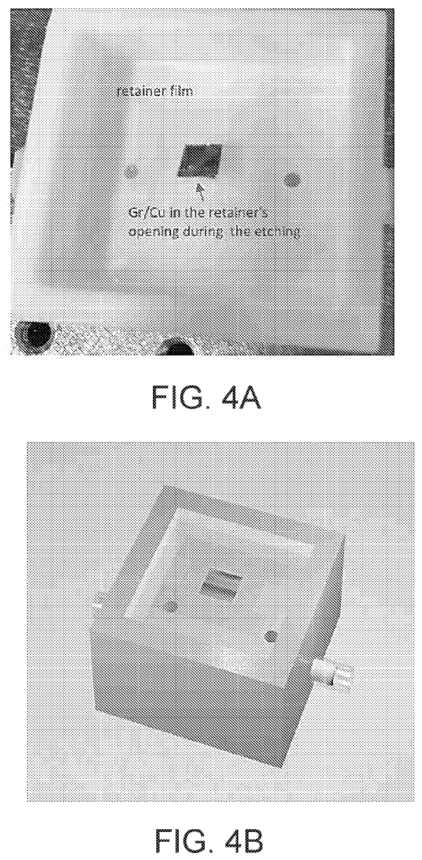

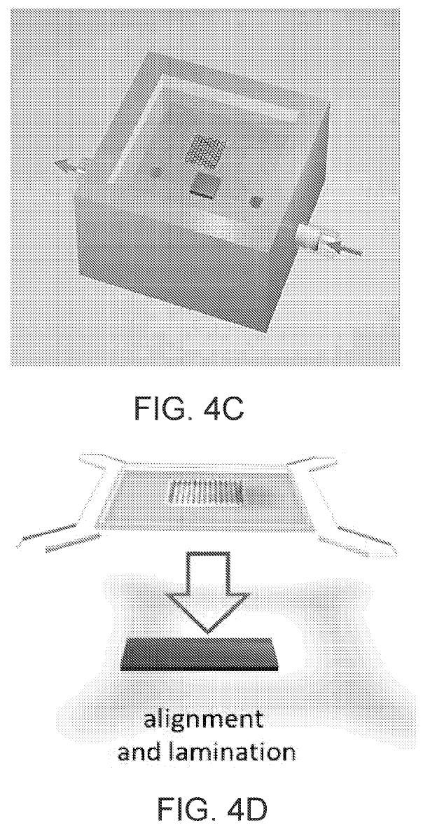

For transferring the graphene, an 8 mm×5 mm piece or sheet of graphene/copper was cut that had been grown using the CVD method, and one drop of IPA was placed on the top of the graphene/copper piece/sheet. Then, the graphene/copper piece 116 was placed in the middle opening 114 of the PET retainer frame 112. The retainer frame 112 with the copper/graphene piece 116 was placed in the transfer reactor 106 filled with the copper etching solution 118, as demonstrated in FIG. 2B and also shown in the prototype image of FIG. 4A and prototype model of 4B. The copper etching solution 118 can be successfully replaced with pure DI-water while the graphene piece 116 is confined within the middle opening 114 of the PET retainer frame 112 to protect the graphene piece 116 from any disturbance during the exchange of the liquids. In later trials, pure DI-water was replaced with a mixture of DI-water and IPA with a ratio (95% DI: 5% IPA). Initial measurements indicated that the final ST of the mixture was approximately 47 dyne/cm, which represents a STG of approximately 25 dyne/cm. Later, the percentage of IPA in the mixture was increased to 10%. In this case, the final surface tension is 37 dyne/cm, which represents a 35dyne STG. Finally, a solution of DI-water/IPA was inserted with a ratio (80:20%) which reduces the ST to approximately 32 dyne/cm, representing a 40 STG from the initial ST of water, as shown in Table 1 (FIG. 3A). Next, a 300 nm SiO₂ substrate 120 was inserted into the reactor 106 and aligned underneath the graphene sheet 117, as illustrated in FIG. 2C and FIGS. 4C-4D. The SiO₂ substrate had been previously cleaned with a mixture of sulfuric acid and hydrogen peroxide (3:1), and was then rinsed with DI-water, and O₂ plasma was then used to activate and enhance the substrate hydrophilicity.

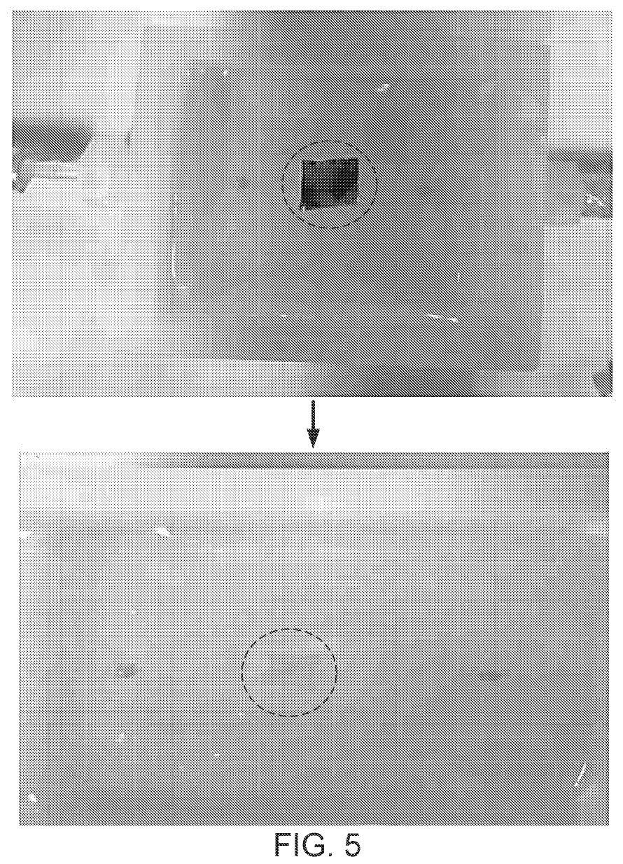

In the transfer reactor 106, after positioning the SiO₂ substrate 120 under the graphene sheet 117, the mixture of DI-water and IPA was pulled from both sides using the side ports or syringes 108, 110, which results in lamination of the graphene 117 on the top of the SiO₂ substrate 120. Thus, in various embodiments, as a final step of laminating graphene on the substrate, water is removed using both side-openings 108, 110 of the reactor in order to position the graphene on a center of the substrate. For comparison purposes, the above trial was repeated using a mixture in which the IPA percentage was 30%. In this case, the STG increased to 46 dyne/cm. Although this repeated procedure raised the STG by only 6 dyne/cm extra, it produced noticeable damage on the graphene structure. Later, in a subsequent trial, graphene was defective by enabling oxygen leakage during the graphene growth and the trial was repeated by lowering ST gradually using DI-water/IPA mixtures with the previously mentioned ratios. In this case, it was noticed that graphene tore up immediately after reducing the ST from 72 dyne/cm to 47 dyne/cm. The defective graphene showed initial defects after the copper was fully etched, such as macroscopic holes, edge deformations, and edge cracks. Such defects will be aggravated after applying STG, even at small values. This finding indicates that high ST contributed to manifesting the graphene flaws formed during the growth, while STG only exacerbated their effects. In general, graphene with less quality shows different features after the copper is fully etched, such as edges of defective graphene deformed to a star shape, as highlighted by the dashed circle in FIG. 5. To confirm that graphene that withstands high ST (ST of water) can be transferred without any sign of damage, we achieved a transfer to a transmission electron microscopy (TEM) grid. For this goal, the lacy carbon grid on copper with 400 mesh from Ted Pella was used. It is worth mentioning that in all the above embodiments, the flowrate of all inserted liquids was maintained to be 1 ml/2 s.

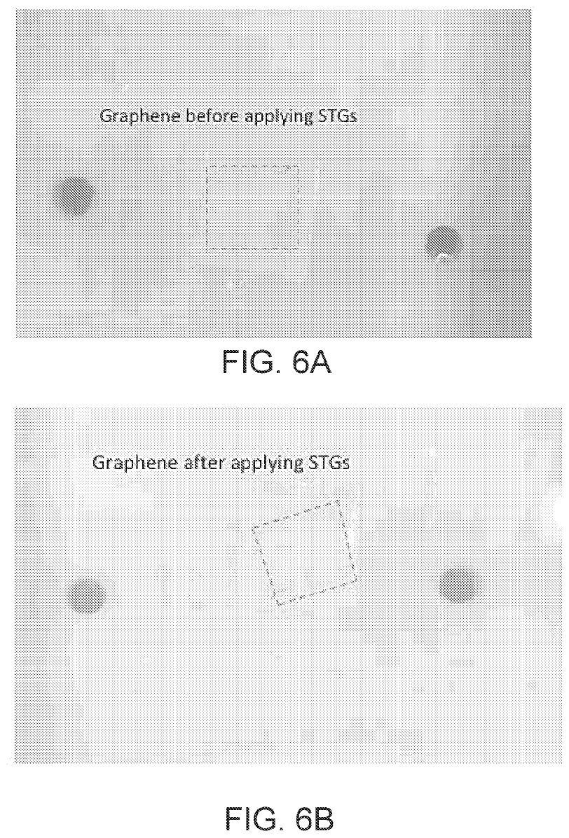

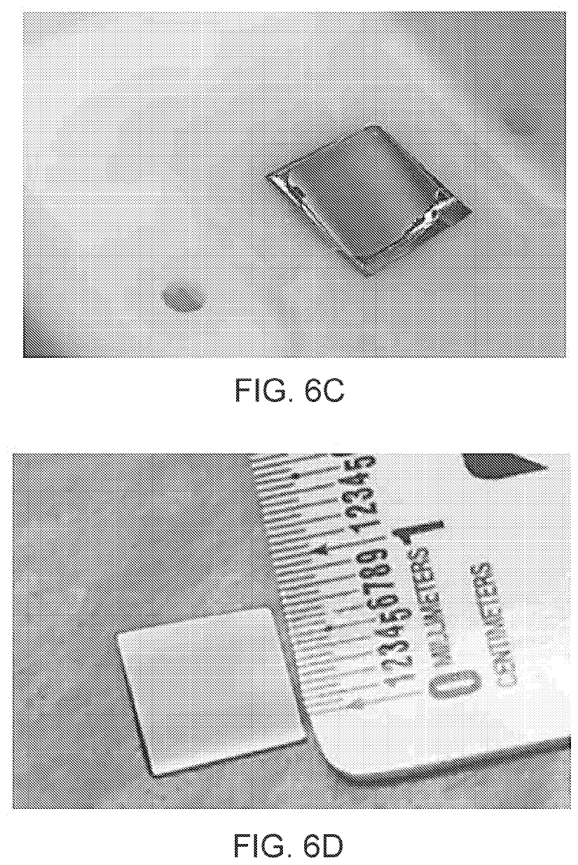

According to the above embodiments, two different cases were examined. FIG. 6A shows a monolayer graphene sheet or piece floating on pure water before the ST reduction. FIG. 6B shows the same graphene sheet after reducing the ST of water by applying several STGs on it in sequence. The STG applied on the graphene sheet gradually increased from 25 dyne/cm to 40 dyne/cm. Finally, the graphene sheet/piece was transferred to the SiO₂ substrate, as shown in FIG. 6C. During and after these transfer processes, no sign of damage to the graphene was observed. FIG. 6D shows an intact graphene piece transferred successfully on the target substrate. This result indicates that the quality of graphene plays an important role in succeeding at the direct transfer. In addition, there is no real need to achieve ST matching of the etching solution and the rinsing solution because graphene can withstand STGs from 25 dyne/cm to 40 dyne/cm. On the other hand, it was noticed that defective graphene shows deformation after the copper is fully etched, as previously shown in FIG. 5.

The foregoing shows that graphene with initial defects will exhibit a clear feature of deformation after reducing the ST by only adding a small amount of IPA (5%) to reduce the ST from 72 dyne/cm to 47 dyne/cm. Eventually, after increasing the amount of the lower ST liquid, the edges obtained larger cracks and small graphene pieces separated from the main graphene piece. To explain why defective graphene cannot withstand a STG, it is suggested that an interface is created in between the initial liquid and inserted liquid with less ST. When the graphene is defective (e.g., the graphene has visible cracks on the edges), the liquid interface will not only fold the graphene edges but also will find a way inside the graphene sheet because of the large cracks. And, lastly, the graphene will be torn into a few pieces. Comparing those results with a good quality graphene leads one to consider that withstanding high ST and STG is an intrinsic feature of good quality graphene.

Although graphene can withstand high ST and STGs, it is impracticable to fully replace the DI-water (72 dyne/cm) with IPA (21 dyne/cm). After making the graphene float on an IPA mixture with ST around 32 dyne/cm, the IPA percentage was increased to 30% to reduce the ST to 26 dyne/cm. In this case, it was observed that the graphene obtained a noticeable deformation by the resulting increase in the STG to 46 dyne/cm. In the case where ST reached 26 dyne/cm, the graphene would be impacted no matter the quality of the graphene. The detailed description of this process is as follows: When inserting a liquid mixture of 30% IPA and 70% DI-water, an interface will be created in between the initial liquid and inserted liquid with less ST. This liquid interface keeps proceeding or moving with increasing the rate of the new liquid. Since the surface tension gap can cause turbulence, the interface between the initial liquid and the inserted liquid keeps moving as the new liquid is added (due to the resulting turbulence). This process leads to shrinkage on graphene edges. The graphene was observed to have a small shrink in the edge after inserting 25% IPA, which indicates a collapse in the graphene structure. Eventually, the graphene tore up on the same side of the IPA mixture insertion. Since graphene tore up suddenly, it is assumed that even if graphene has good quality, a few micro-cracks can still exist on the edges. They are understood to contribute to tearing graphene while applying high STG. Such microcracks beside the interface of the two liquids can be the main reasons for tearing graphene eventually. A similar effect can happen in the case where etching solution was replaced directly with 30% IPA. The liquids interface suggested in this discussion is also produced in all ST tuning trials; but at STGs≤40 dyne/cm, there is no damaging effect on graphene structure. However, applying a STG≥46 leads to visible collapse of the graphene sheet. This result confirms that it is unachievable to replace all of the DI-water with IPA.

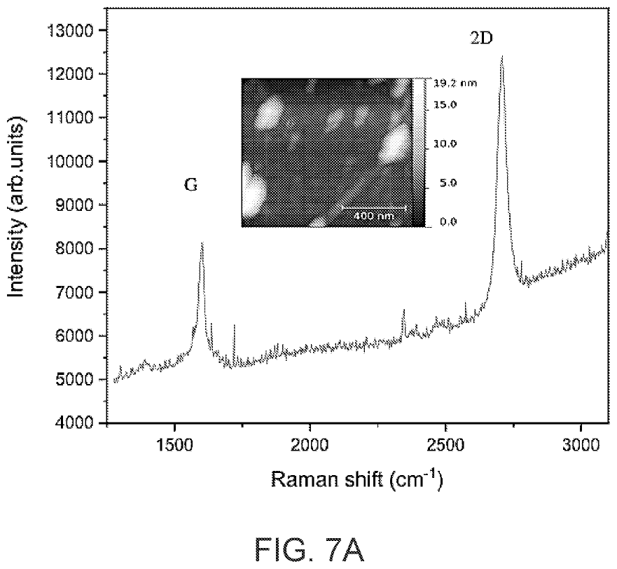

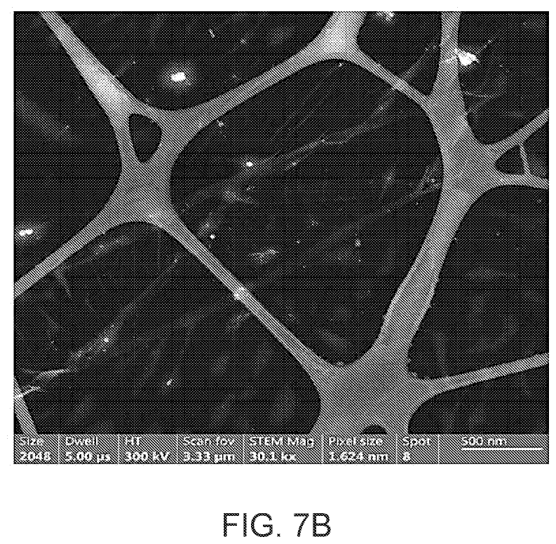

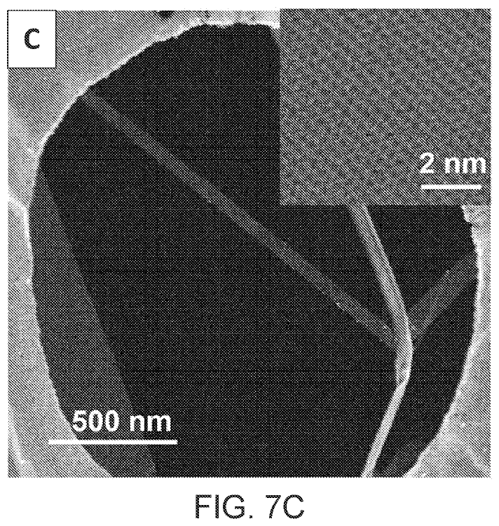

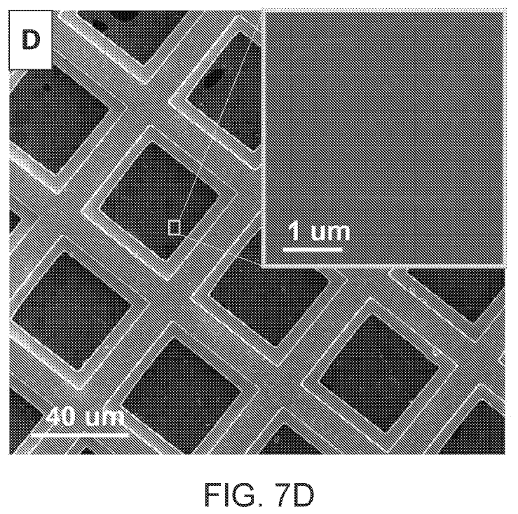

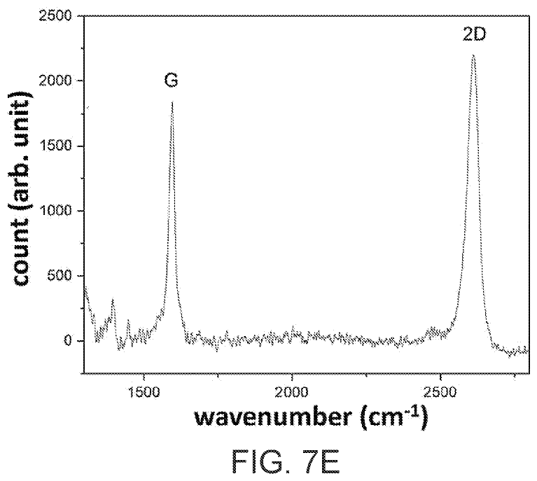

As is known, monolayer graphene can be determined initially by Raman signal. The Raman shift of graphene that transferred after applying the maximum STG on it was measured using a confocal Raman microscopy (CRM) equipped with a tunable Argon ion laser (514.5 nm). FIG. 7A indicates the Raman shift of the single-layer graphene, where we note the exact features of single-layer graphene; that the 2D band has a sharp symmetric peak, and that it is almost double the G intensity. Atomic force microscopy (AFM) was used to achieve a scanning image of the transferred graphene, as shown by FIG. 7A (inset). According to AFM scanning, the RMS roughness of graphene is approximately 2.9 nm. Although we can notice some nano-droplets of water have been trapped in between graphene and the substrate, graphene annealing was avoided since there are no chemical residues on the transferred graphene. Besides Raman signal and AFM, graphene was also transferred on a TEM grid. The image shown in FIG. 7B is a continuous single-layer graphene with no defects, transferred with pure DI-water on the 400 mesh TEM.

Accordingly, one obvious benefit of this GWM is the ensured cleanness of the graphene layer by eliminating the usage of PMMA or other supporting media for processing. Thus, small organic molecules dispersed in the air turn out to be the only contamination source, which can be readily removed by afterward annealing. Indeed, the transition electron microscopy (TEM) image shown in FIG. 7C reveals a very clean graphene surface rendered by the GWM, and the scanning TEM (STEM) can clearly distinguish individual carbon atoms.

Besides the ultra-cleanness, another striking significance of the GMW distinct from other process methods is a one-step and direct graphene suspension without any assistance of supporting media or supercritical drying employed in earlier studies. FIG. 7D shows the scanning electron microscopy image of a graphene suspension directly obtained by transferring a GMW on a mesh TEM grid with 40×40 μm² openings. The inset magnification exhibits the uniform and flawless graphene layer. This one-step graphene suspension can be attributed to the high graphene quality, and more importantly, the reduced amount of water adhered to the graphene surface when the GMW forms, as indicated by our molecular dynamics simulation that no water adheres to the graphene layer when the GWM is peeled from the water surface. Therefore, the GWM can drastically simplify the procedure for large-scale suspended graphene and other 2D material structure constructions.

Based on the free-suspended graphene, we also performed Raman characterization, as shown in FIG. 7E, which shows no signal of amorphous carbon.[18] The reduced 2D/G peak ratio is well-known for free-standing graphene that is charge neutral, further suggesting the contamination-free surface of the graphene produced by the GWM.

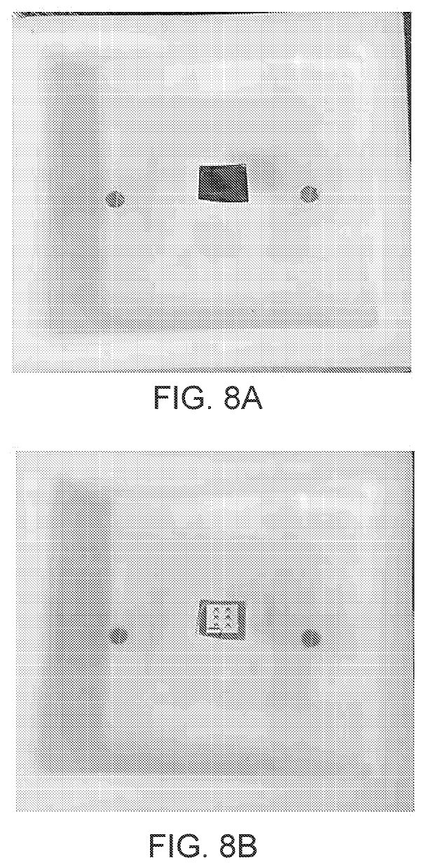

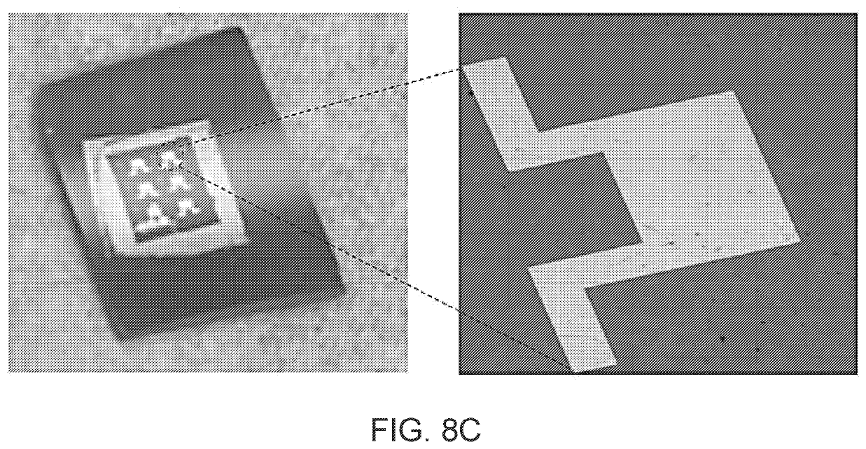

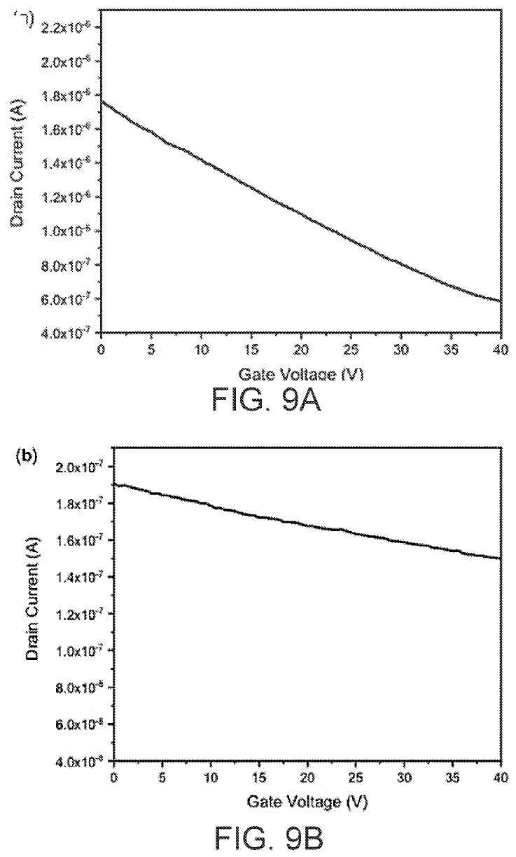

After unveiling the true impact of surface on graphene transfer, whole device transfer was achieved in various embodiments, such that a microstructure device (e.g., FET device, etc.) can be fabricated on graphene/copper and can be transferred to the target substrate, such as, but not limited to, a metal, silicon, silicon dioxide, a semi-liquid substrate, etc. Accordingly, after chemical vapor deposition of graphene, patterns on graphene/Cu were created via lithography. A thermal evaporator was used to achieve the metal deposition (Ti: 5 nm, Au: 45 nm). Next, acetone was used to accomplish the lift-off process. Later, after the copper was fully etched, the device/graphene was rinsed with only DI-water to remove the etching solution and copper residues. Finally, water was removed slowly using the side syringes (each located at the source inlet and drain outlet) to laminate the whole device/graphene on the SiO₂ substrate, as illustrated in FIGS. 8A-8C. To demonstrate the electrical properties of graphene, FET mobility of the two types of graphene was measured. Graphene with a high quality was found to have mobility μ=950 cm²V⁻¹s⁻¹, which is 95 times higher than the mobility in the defective graphene. FIGS. 9A and 9B show the mobility of both types of graphene transferred on 300 nm SiO₂. Indium wires were functioned to fabricate the FET terminals.

Thus, high quality graphene can withstand high ST, while defective graphene does not show the same feature. Matching surface tension values of the etching solution and rinsing liquid has no importance in the present method because, graphene could withstand a maximum surface tension gap of approximately 40 dyne/cm. Based on these results, there is no need to reduce the water surface tension to achieve the direct transfer of graphene, as long as a high graphene sample quality is ensured. Observations from the present results remove the long-standing illusion that a high ST can damage graphene during the polymer-free transfer process. More importantly, it indicates the flexibility in the selection of transfer liquid specific to various application purposes.

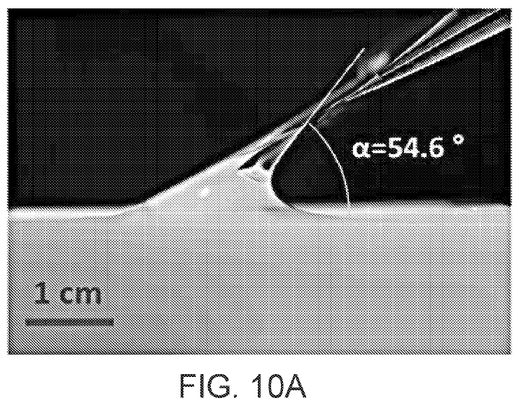

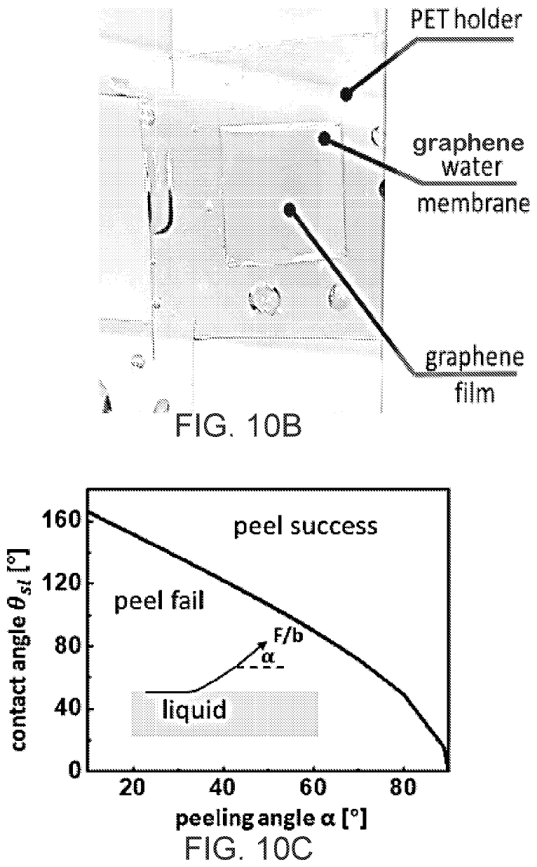

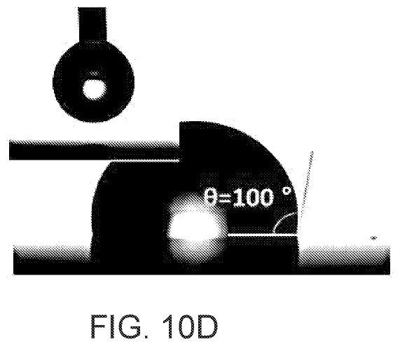

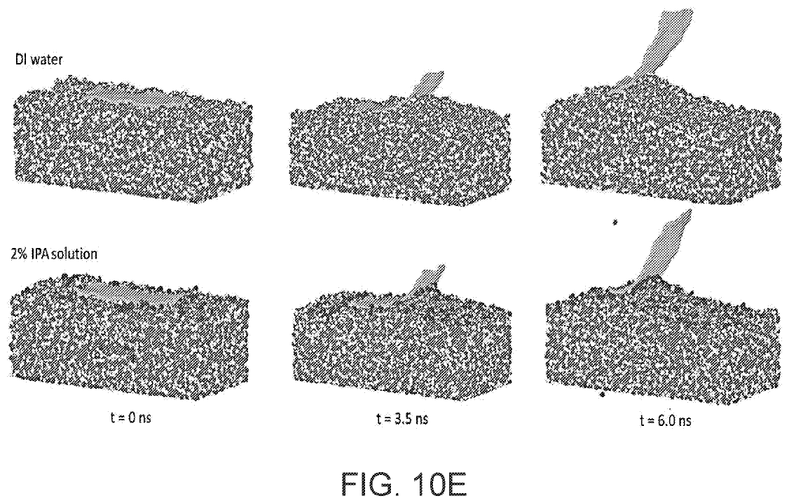

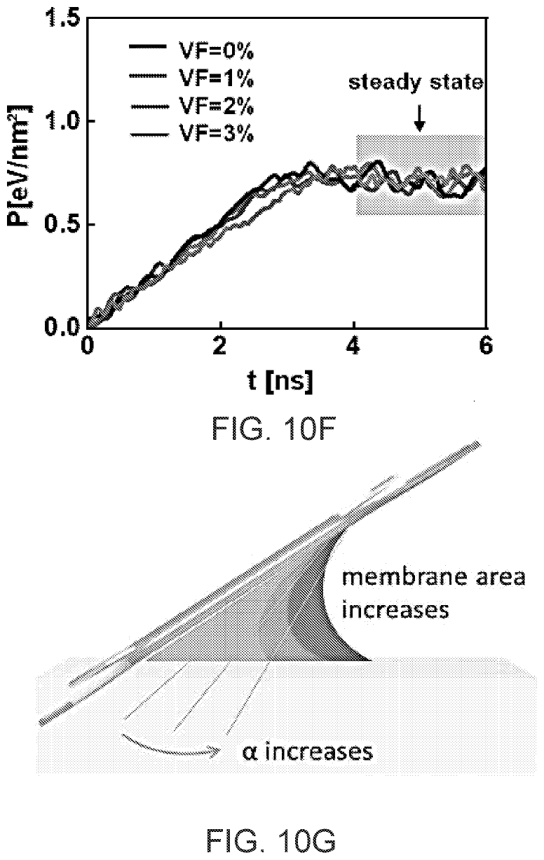

The present results show that CVD graphene can withstand the high surface tension of DI water as long as the described precautions are followed. Otherwise, defects developed during growth and physical damage due to improper handling can impair the graphene layer, leading to cracks, wrinkles, shrinking, etc. Accordingly, when a graphene layer is successfully isolated and freely floats on the water surface, the free-floating graphene layer can be peeled off the water surface by lifting the PET frame from the reactor. This peeling process has been recorded in the optical image shown in FIG. 10A. During this step, a water film bridges the graphene layer to the inner edges of the PET frame and pulls it away from the liquid surface. The film buffers the fragile graphene from the PET frame, preventing the sharp edges of the PET frame from piercing the atomic layer, while still distributing the necessary force for peeling. After the entire graphene layer is levered away from the water surface, the GWM shown in FIG. 10B emerges.

To better interpret the peeling process, a mechanical peeling model is used. Specifically, two dominating factors are considered that determine a successful peeling: (1) the driving force provided by the water film that bridges the graphene and the inner edges of the PET frame and helps peel off graphene and (2) the adhesion between the graphene layer and liquid surface to be overcome during peeling. The driving force per unit width (D) is provided by the surface tension (γ_{ι}) of water in the form of D=2γ_{ι}. The force per unit width (P) required to peel the graphene can be derived from the energy balance between the work done by the peeling force and the variation of graphene/liquid interfacial energy,

$$P = \frac{{γ}_{l} \times ( 1 + cos {θ}_{s l} )}{1 - cos α} \qquad ( 1 )$$

where θₛₜ denotes the contact angle between graphene and water, and α labels the peeling angle as defined in the inset of FIG. 10C. For a successful peel, we will have D≥P, i.e.,

$$α \geq arccos [ \frac{1 - cos {θ}_{s l}}{2} ] . \qquad ( 2 )$$

For DI water on graphene, the contact angle of 100° (FIG. 10D) was determined using a goniometer (DataPhysics OCA 15EC), which takes place within the reported range of 95˜100°. A theoretical prediction resulting from Equation (2) shows a minimum peeling angle of 54.1° for a successful peeling of graphene from the water surface. This is consistent with the observation of 54.6° shown in FIG. 10A. FIG. 10C is a diagram for picking up the graphene from a liquid surface and the relationship between contact angle and peeling angle. A smaller contact angle associated with stronger hydrophilicity between graphene and liquid will require a more powerful driving force, and thus a larger peeling angle for a successful graphene lifting.

Additionally, molecular dynamics (MD) simulations were performed on the entire peeling process. A graphene film with 4 nm×10 nm was placed on the surface of the liquid and peeled by applying a mechanical force with the peeling angle of 57.5° at a velocity of 1 nm/ns. FIG. 10E shows the simulation snapshots of peeling graphene from water at 0, 3.5, and 6.0 ns, suggesting a neat peeling of graphene film without liquid molecular residues on the peeled graphene. FIG. 10F further plots the evolution of the peeling force as a function of peeling time and implies an equilibrium (steady state) has been achieved 4 ns after the peeling began. The peeling force at the steady state is 115.5 mN/m when pure water is employed, which agrees with the theoretical prediction of 128.6 mN/m by Equation (1) with a water surface tension of 72 mN/m.

The peeling process was also considered when IPA is added to the DI-water to comprehend the effects of lower surface tension and contact angle. In various embodiments, the graphene layers were successfully peeled out of 1% and 2% IPA solution with peeling angles of 55.5° and 57.0°, respectively, which further confirms the theoretical prediction of the “successful peel” region shown in FIG. 10C. Molecular Dynamics (MD) simulations also indicate that the peeled graphene remains clean without residual IPA molecules, similar to peeling from the water surface, as shown in FIG. 10E. As the IPA concentration increases to 3%, the liquid (water with 3% IPA) results in the graphene water membrane breaking before the graphene is fully peeled off. Consequently, the entire process fails because a higher IPA concentration decreases the contact angle and necessitates a larger peeling angle, which in turn stretches the liquid membrane until it breaks before the whole graphene layer is lifted from the liquid surface. Quantitively, the MD simulation shows that a 3% IPA solution leads to a 94.5° contact angle and requires at least a 57.4° peeling angle, which will break the liquid membrane between frame and graphene and fail to pick up the graphene. The peeling force remains approximately the same as a small amount of IPA barely influences the contact angle of the water, as suggested by theoretical predictions. Correspondingly, FIG. 10G is a model image of a graphene peeling process and the relationship between a smaller contact angle requiring a larger peeling angle and a resulting increased risk of peeling failure in accordance with the present disclosure.

The discussed trial and theoretical analyses indicate that high-quality graphene can readily withstand the high surface tension of water. Interestingly, leveraging the large contact angle between graphene and water (i.e., high hydrophobicity), a stable GWM forms when free-floating graphene is peeled out of the water surface with a retainer frame structure. In addition to contributing to the understanding of graphene-water interaction and exhibiting a new hybrid membrane structure, the GWM further leads us with a new large-scale polymer-free graphene transfer technique with excellent outcomes. Like other polymer-free processes, no PMMA or other thin-film is coated for graphene protection. Therefore, there are no organic molecules accumulated on the graphene layer. Moreover, compared with previously reported polymer-free methods, an exemplary transfer of the present disclosure renders a much better flatness and electronic performance.

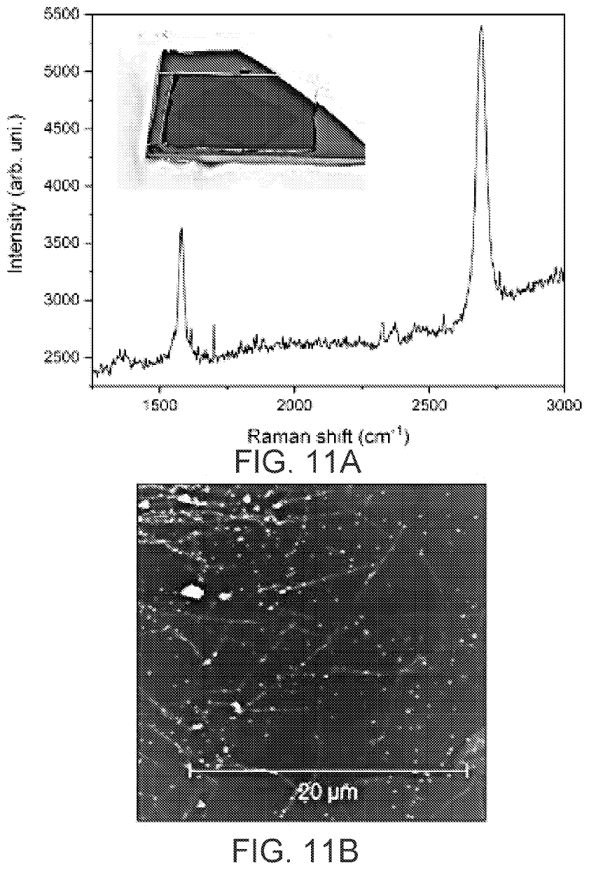

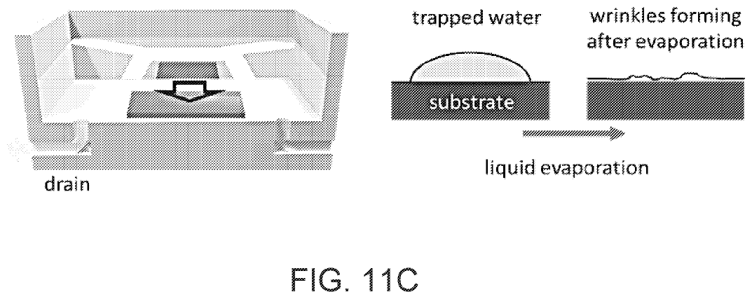

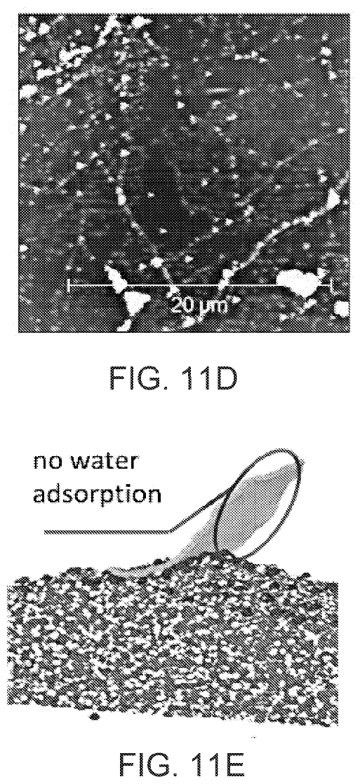

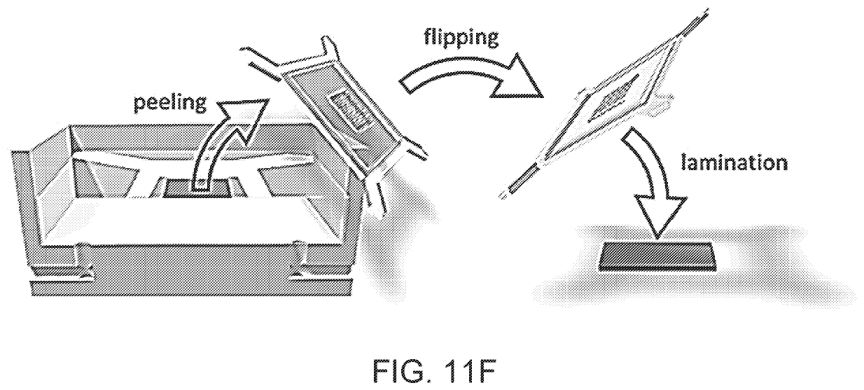

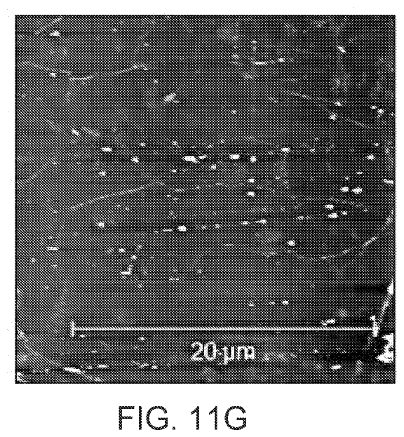

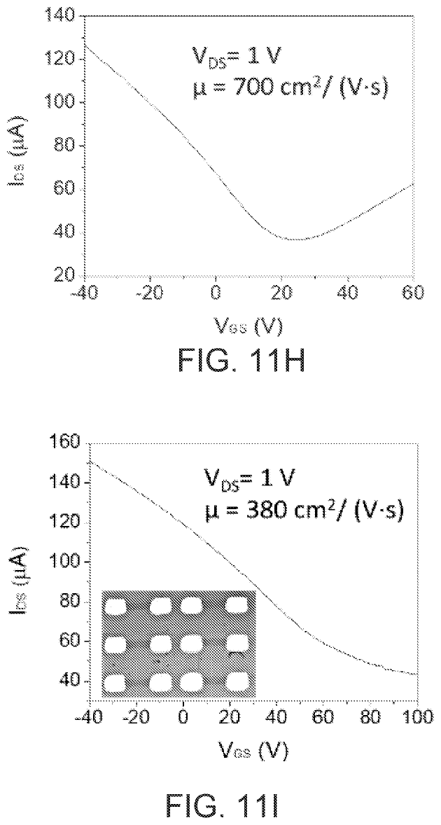

As shown in FIG. 4D, the free-floating graphene layer can be picked up from the water surface with the PET retainer frame, then aligned, and laminated onto the target substrate. Accordingly, certain example embodiments relate to the use of graphene as a transparent conductive coating, where the graphene thin films of certain example embodiments may be doped or undoped. Here, Si wafers are employed with a 300 nm SiO₂ layer as the substrates to perform the transfer trial. They are cleaned with piranha solution (H₂SO₄: H₂O₂ (37%)=4:1) to remove organic residues thoroughly. FIG. 11A and its inset show the optical image of high-quality large-area graphene transfer performed with the above procedure, indicating that the sample's integrity is fully preserved without visually detectable cracking or wrinkling. The Raman spectroscopy measurement, shown in FIG. 11A, clearly distinguishes the sharp G and 2D peaks with an intensity ratio of 1:2, whereas the D peak is very weak. These observations indicate a monolayer graphene with excellent quality. To further confirm the microscopic structure and flatness, an atomic force microscopy (AFM) study was conducted on the graphene transferred with an exemplary graphene transfer method and confirmed a low morphology roughness (i.e., the root mean square (RMS) of the surface height) of 1.5 nm (see FIG. 11B). Graphene grain boundaries can also be clearly distinguished on the AFM image. In comparison, the transfer following the conventional polymer-free method, as shown in FIG. 11C, results in the roughness of 3.4 nm (see FIG. 11D).

One primary reason for this drastic improvement can be attributed to the water film, which bridges the PET frame and graphene layer while stretching and flattening the atomic layer with its surface tension. A potential concern of the graphene-water structure is whether the large surface tension can tear the graphene layer after it is lifted from the water surface. To determine this, the following analysis was performed. Considering the Young's modulus (E) of monolayer graphene being approximately 2.0 TPa and a graphene thickness (t) of 0.33 nm, the strain (ε) on monolayer graphene induced by the water surface tension (γ_{water}) was calculated via the Equation 3 as:

$$ε = \frac{2 {γ}_{water}}{E t} . \qquad ( 3 )$$

Equation 3 shows that the surface tension only results in a strain of 0.02%, far below the fracture strain of graphene. However, if there are microscale defects (e.g., predominantly if pores or cracks are present), they can rapidly grow under strain and cause brittle fractures to the polycrystal CVD graphene. Thus, the formation and stability of the water-graphene membrane strongly depend on the quality of the graphene layer rather than the water surface tension. The membrane can readily form and flatten the graphene layer as long as the graphene quality is maintained.

Another reason for the much higher transfer quality is that less liquid is trapped on the graphene-substrate interface in an exemplary transfer procedure than the conventional polymer-free transfer technique, as confirmed by MD simulations in FIG. 10E. In the conventional polymer-free transfer methods, target substrates are typically fully merged into the transfer liquid (water or IPA mixture), as illustrated in FIG. 11C. Then, the liquid is drained out of the container to lower the graphene layer until it is in contact with the target. This procedure inevitability creates multiple pockets of trapped liquid on the graphene-substrate interface. Even after the trapped water eventually evaporates, folding, wrinkling, or other deformations can still persist, as illustrated in FIG. 11C, and lead to the as-observed RMS roughness of 3.4 nm. This problem is detrimental to the subsequent device fabrication and testing. Nevertheless, an exemplary transfer approach can be effectively addressed in such a manner that the hydrophobic nature of graphene repels most of the water accumulated underneath the graphene layer unless minor residuals are anchored by hydrophilic functional groups, including hydroxyl, due to unintentional graphene oxidation. Undeniably, MD simulations further confirm that water molecules do not adhere to the graphene layer being peeled off, as shown in FIG. 11E, even if IPA is added and lowers the graphene contact angle. To eliminate the minor interfacial residues or contaminants, the entire PET frame with a graphene-water membrane can be flipped or overturned in order to laminate the “dry” surface of the membrane onto the target substrates. FIG. 11F highlights the workflow of this flip-transfer method. By doing so, one finds that the roughness of the resulting transfer is improved to 0.7 nm (see FIG. 11G), which is close to the intrinsic roughness of SiO₂ (0.4 nm).

The ultimate purpose for large-scale, high-quality graphene transfer is to develop next-generation high-performance electronic devices. To this end, field-effect transistors (FET) are fabricated with the same batch of graphene layers transferred with the conventional and the improved polymer-free transfer approach of the present disclosure, and plots of their respective translation curves are shown in FIGS. 11H and 11I for comparison. The FET made with the conventional polymer-free method (FIG. 11C) yields a mobility of 380 cm²V⁻¹s⁻¹, whereas the newly improved method renders a significant improvement up to 700 cm²V⁻¹s⁻¹. This drastic performance-boosting can be attributed to the much better transfer quality with decreased graphene roughness, where roughness can lead to lattice deformation, charge carrier scattering, and many other degradations that compromise the charge carrier mobility and device performances. It is worth noting that all these measurements are performed on regular Si/SiO₂, and even better FET characteristics can be expected if hexagonal boron nitride (hBN) is employed. Even so, the successful enhancement on the regular substrate shows more promised fabrication scalability for practical applications.

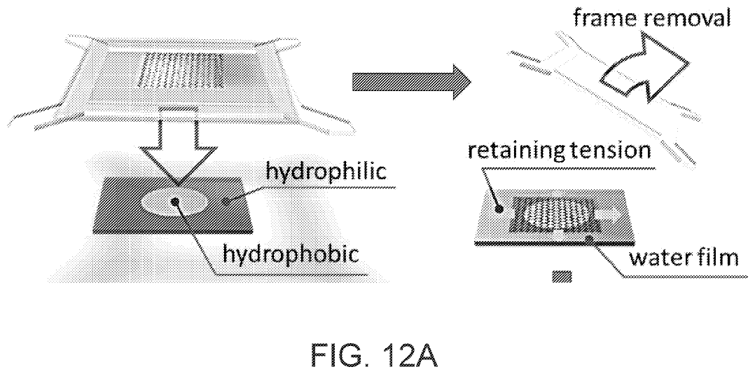

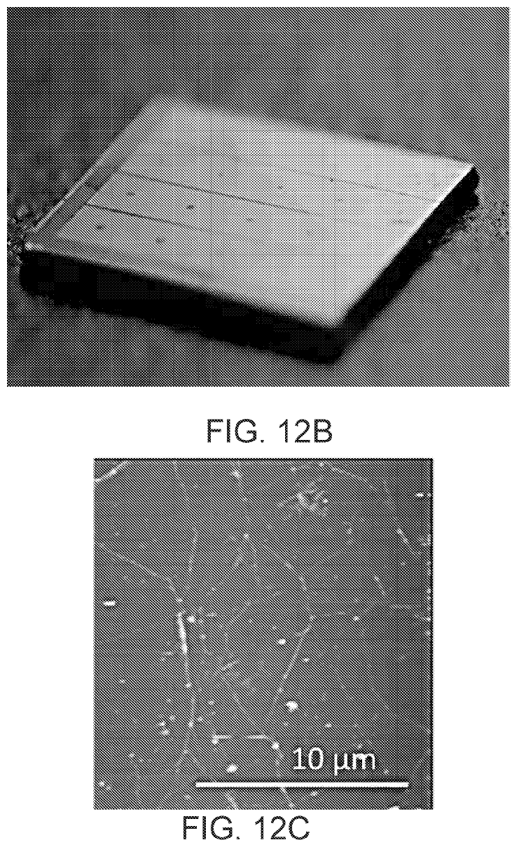

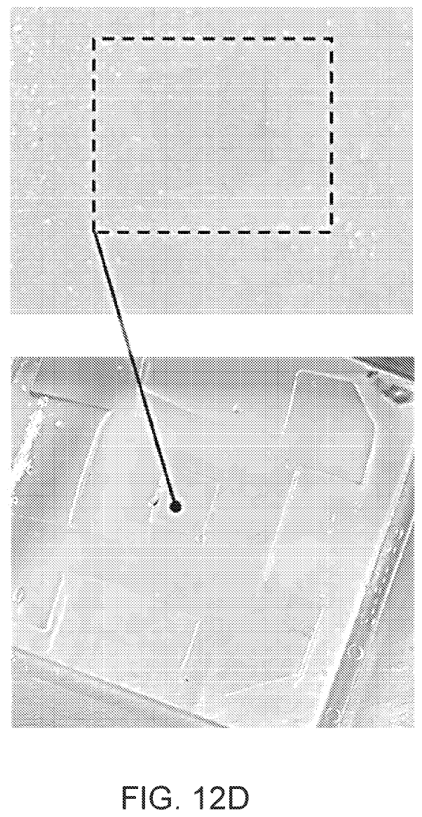

Aside from the above discussions on surface tension, peeling processes, and membrane flipping, substrate factors were identified, particularly the hydrophilicity effect on the success and quality of the exemplary transfer method. Accordingly, it is noted that a hydrophilic substrate can sufficiently sustain the integrity of the water membrane and thus the graphene layer. The water keeps tensioning the graphene layer until it fully volatilizes and leaves a highly flat morphology. However, if the target substrate is highly hydrophobic, the water film bridging collapses and drags the entire graphene layer to one side of the PET frame instantaneously when it touches the surface, failing the transfer. To overcome this problem and enable the transfer onto a hydrophobic substrate, a hydrophilic frame surrounding the hydrophobic area is introduced in various embodiments to stabilize the graphene-water film and sustain the tension until the transfer is finished, as demonstrated in FIG. 12A. For example, a SiO₂ frame was patterned on Si substrate, as shown in FIG. 12B, through a thermal oxidation process to form a Si-graphene junction. The entire substrate was treated with hydrogen fluoride acid (5% aqueous solution) before the transfer to passivate the silicon area with hydrogen atoms and produce a hydrophobic surface, whereas the SiO₂ frame remains hydrophilic. With the assist of the hydrophilic frame, graphene was successfully transferred onto the Si and ultra-high flatness was obtained, as verified by the AFM image in FIG. 12C. Other hybrid structures can also be produced with the same method. Further, FIG. 12D illustrates that the newly developed method can effectively transfer graphene to other unconventional substrates, such as hydrogel (depicted in FIG. 12D) and other soft-matter substrates, whereas earlier polymer-assisted or polymer-free methods are infeasible because the organic solvent for the afterward cleaning or the full liquid transfer environment can easily damage the hydrogel structure. Therefore, an exemplary method also facilitates the fabrication of large-scale hybrid structures of graphene and soft matters for the applications of biosensors, wearable devices, and many more.

In brief, the present disclosure presents a new GWM structure and based on this new structure, an improved graphene transfer method is provided with drastically improved transfer flatness and electronic performances, in part due to the high surface tension of water, which retains the graphene flatness through the entire pickup, alignment, and lamination workflow. These benefits provide an alternative approach for high-performance device fabrication based on graphene and other low-dimensional materials.

Improved systems and methods of the present disclosure provide a variety of advantages over the prior art, such as, but not limited to: The usage of only DI-water and PET film with a specific cut to achieve the direct transfer of graphene, which means no contamination sources can affect the final graphene quality; functioning high surface tension (ST of water to achieve the transfer); saving time & efforts and maintaining the quality of graphene to obtain excellent results as compared to the existing conventional methods of the direct transfer; providing a clear molecular dynamic description of Graphene/Water/Membrane (GWM) and how this combination is functioned to achieve successful transfer; reducing the mean roughness of transferred graphene to less than 0.9 nm compared to the conventional way of transfer which reaches 3 nm; allowing the transfer of graphene to flexible and semi-liquid substrates such as ionic hydrogel which can be widely used in the field of highly sensitive pressure sensors; enabling transfer of graphene, which is a two-dimensional (2D) material, to any type of substrate, such as a semiconductor, metal, or organic substrate; enabling the graphene coating of substrates that could not have been coated with prior art methods, such as porous surfaces and hydrogels, since exemplary methods do not require immersing the substrate in water; widening bio-applications, such as laminating graphene on cells to achieve scanning electron microscopy; among others.

Apart from the prior art, the disclosed methods and systems can be achieved without polymer assistance. In an exemplary method of the present disclosure, graphene can be confined in a PET retainer frame that is not coated on graphene edges, such that graphene can be peeled from the water surface and delivered using the PET film. Therefore, no graphene is wasted and any type of substrate can be targeted using this method. Additionally, an exemplary method of the present disclosure facilitates a simple and promising method to achieve graphene transfer, without any additional coatings and mechanical force being applied, and no need for vacuum annealing that is known for disturbing the pristine electrical property in a monolayer graphene sheet in some prior art methods.

The present disclosure refers to various methods. Additional details on certain disclosed methods are provided below.

CVD growth of graphene. A CVD system had been used to grow the monolayer graphene. We electropolished 0.025 mm copper foil (CU000358 from Goodfellow) in mainly 80% phosphoric acid (H₃PO₄) to achieve the graphene growth later at 1000° C. by controlling methane (CH₄) flowrate at 35 sccm and a mixture of argon and hydrogen (Ar 90%: H₂ 10%) at 6 sccm.

Copper etching. To etch copper, we dissolved 200 gm of ammonium persulfate ((NH₄)₂S₂O₈) (from Sigma-Aldrich) in 200 ml of DI water to prepare 0.1 M concentration.

Hydrogel substrates were prepared by mixing 1 gm of agar powder and 1 gm of gelatin sheets in 10 ml of boiling water. The mix was poured later in a plastic mold and left to solidify for 20 minutes.

Characterization. A confocal Raman microscopy consists mainly of an argon-ion laser 514.5 nm combined with an Andor Shamrock 500i imaging spectrometer to check graphene Raman signal. We performed AFM scanning of graphene on the Veeco MultiMode AFM system under tapping mode. The measurements of electron mobility on graphene FET devices were done on a probe station combined with a source meter unit (SMU, Keithley 2450).

FET device Fabrication. We fabricated shadow masks by following photolithography methods. Later, we used the electrodes shaped mask to deposit Cr 5 nm/Au 45 nm using a thermal vapor deposition system (thermal evaporator EDWARDS Auto 306). Finally, we shaped transfer graphene to narrow channels (width=1 mm) using radiofrequency argon plasma and the strips' shadow masks.

MD simulations. All MD simulations were carried out by the Large-scale Atomic/Molecular Massively Parallel Simulator (LAMMPS) package. Graphene with a width of 4 nm and a length of 10 nm was placed on the surface of the liquid mixture of water and IPA with 42000 water molecules. The simulation box size for peeling was 9.947 nm×20.4192 nm×20.0 nm, and the adaptive intermolecular reactive bond order (AIREBO) modeled flexible graphene. The SPC/E and TraPPE-UA potential models were adopted for water and IPA molecules, respectively. For the nonbonded interactions, the 12-6 pairwise Lennard-Jones potential V(r)=4ε(σ¹²/r¹²−σ¹²/r¹²) and Coulomb interaction V_{q}(r)=qᵢqⱼ/4πε₀r were applied where r is the interatomic distance. At the same time, σ and ε are the equilibrium distance and the interactive well depth of the potential, respectively, qᵢ and qⱼ are the electronic charge counterpart, and co is the permittivity of the vacuum. Specifically, the Lennard-Jones parameters for graphite-water interaction were σ_{co}=3.19 Å and ε_{co}=0.00407 eV. The cut-off distance was 1 nm in this study. The Lorentz-Berthelot mixing rule was used to determine the inter-L-J parameters for different components. The particle-particle-particle-mesh (PPPM) algorithm with a root mean of 0.0001 was used to minimize the error of long-range Coulombic interactions. All simulations were run in an NVT ensemble with a Nose/Hoover thermostat set at 300 K unless otherwise stated.

It should be emphasized that the above-described embodiments are merely possible examples of implementations, merely set forth for a clear understanding of the principles of the present disclosure. Many variations and modifications may be made to the above-described embodiment(s) without departing substantially from the principles of the present disclosure. All such modifications and variations are intended to be included herein within the scope of this disclosure.

Therefore, at least the following is claimed:

1. A method of transferring graphene on a target substrate comprising:
growing a graphene layer on a metal catalyst substrate to form a graphene/metal sheet;
positioning the graphene/metal sheet in a transfer reactor container, wherein the graphene/metal sheet is confined within an opening of a retainer frame that is also positioned in the transfer reactor container;
introducing an etching solution to the transfer reactor container that removes the metal from the graphene/metal sheet to form a graphene sheet;
replacing the etching solution with a rinsing liquid after removing the metal while the graphene sheet is confined in the opening of the retainer frame, wherein a graphene-water membrane is formed within the opening of the retainer frame as the graphene sheet floats on a surface of the rinsing liquid; and
directly transferring the graphene-water membrane to the target substrate. 2 The method of claim 1, wherein the graphene is grown on two sides of the metal catalyst substrate, the method further comprising removing graphene from one side of the metal catalyst substrate via plasma etching and preserving the graphene layer on the other side of the metal catalyst substrate.

3. The method of claim 1, wherein the metal catalyst substrate is copper.

4. The method of claim 1, wherein the retainer frame is formed from a polyethylene terephthalate (PET) film or comprises a hydrophilic frame.

5. The method of claim 1, wherein the graphene-water membrane is directly transferred by lifting the retainer frame from the transfer reactor container and placing the retainer frame on the target substrate.

6. The method of claim 5, wherein the retainer frame with the graphene-water membrane is lifted and flipped over onto the target substrate.

7. The method of claim 6, wherein a peeling angle at which the retainer frame is lifted is at least 54.1 degrees from a surface of the rinsing liquid.

8. The method of claim 1, wherein the graphene-water membrane is directly transferred by positioning the target substrate under the opening of the retainer frame within the transfer reactor container and drawing the rinsing liquid out of the transfer reactor container.

9. The method of claim 1, wherein no polymers are coated on the graphene during removal of the metal via etching.

10. The method of claim 1, wherein no organic solvents are introduced to remove polymer remnants after transferring graphene to target substrate.

11. The method of claim 1, wherein a surface tension of the rinsing liquid does not match a surface tension of the etching solution used to remove the metal.

12. The method of claim 1, wherein the rinsing liquid is deionized water or is a deionized water and Isopropyl Alcohol (IPA) mixture, wherein an IPA concentration of the rinsing liquid is less than 3 percent.

13. The method of claim 1, wherein the target substrate comprises a semi-liquid substrate or comprises ionic hydrogel or is formed from polytetrafluoroethylene.

14. The method of claim 1, wherein the transfer reactor container comprises a hydrophobic material.

15. The method of claim 1, wherein the target substrate is not immersed in the rinsing liquid during the transfer of the graphene onto the target substrate.

16. A graphene coated substrate comprising:
a target substrate; and
a graphene layer atop of the target substrate,
wherein a surface roughness of the graphene layer on the substrate is less than 2.9 nm.

17. The graphene coated substrate of claim 16, wherein a surface roughness of the graphene layer on the substrate is approximately 0.7 nm.

18. The graphene coated substrate of claim 16, wherein the target substrate comprises a hydrophobic material, a semiconductor, metal, or organic substrate.

19. A graphene coated substrate comprising:
a target substrate; and
a graphene-water membrane atop of the target substrate.

20. The graphene coated substrate of claim 19, wherein the target substrate comprises a hydrophobic material, a semiconductor, metal, or organic substrate.
